(19) United States
(12) Patent Application Publication
(10) Pub. No.: US 2025/0056814 A1
(43) Pub. Date: Feb. 13, 2025

(54) MEMORY DEVICE INCLUDING SWITCHING PATTERN

(71) Applicant: SAMSUNG ELECTRONICS CO., LTD., SUWON-SI (KR)

(72) Inventors: Seulji Song, Suwon-si (KR); Hodae Kim, Suwon-si (KR); Woojun Jeong, Suwon-si (KR)

(21) Appl. No.: 18/796,880

(22) Filed: Aug. 7, 2024

(30) Foreign Application Priority Data
Aug. 9, 2023 (KR) 10-2023-0104353

(51) Int. Cl. H10B 63/00; H10N 70/00

(52) U.S. Cl. CPC H10B 63/24; H10N 70/882

(57) ABSTRACT

A memory device includes a first conductive line, a second conductive line, and a memory cell disposed between the first and second conductive lines. The memory cell includes a lower electrode layer, a switching pattern, and an upper electrode layer. The switching pattern includes a main region including a pair of first side walls and a pair of second walls, and a corner region at four corners of the main region. The switching pattern includes a chalcogenide layer including a Group VI chalcogen element, an element of Group IV and an element of Group V, and the concentration of the Group IV element in the corner region is greater than that of the Group IV element in the main region, or the concentration of the Group V element in the corner region is greater than that of the Group V element in the main region.

### CROSS-REFERENCE TO RELATED APPLICATION

This application claims priority under 35 U.S.C. § 119 to Korean Patent Application No. 10-2023-0104353, filed on Aug. 9, 2023, in the Korean Intellectual Property Office, the disclosure of which is incorporated by reference herein in its entirety.

### TECHNICAL FIELD

The inventive concept relates to a memory device, and more particularly, to a memory device having a switching pattern.

### DISCUSSION OF THE RELATED ART

As electronic products become lighter, thinner, and smaller, the demand for high integration of memory devices is increasing. A memory device with a three-dimensional cross point structure, in which memory cells are placed at the intersection between two electrodes that intersect each other, has been proposed. A memory device with a cross point array structure may provide for high-speed operation and high operation reliability.

### SUMMARY

A memory device includes a first conductive line extending in a first horizontal direction, a second conductive line extending in a second horizontal direction, and a memory cell disposed between the first conductive line and the second conductive line and extending in a vertical direction. The memory cell includes a lower electrode layer, a switching pattern, and an upper electrode layer sequentially stacked on the first conductive line. The switching pattern includes a main region extending in the vertical direction on the lower electrode layer. The main region includes a pair of first side walls spaced apart from one another in the first horizontal direction and a pair of second walls spaced apart from one another in the second horizontal direction, and a corner region at four corners of the main region and extending in the vertical direction. The switching pattern includes a chalcogenide layer including a Group VI chalcogen element of a periodic table, and an element of Group IV and an element of Group V of the periodic table, which are chemically bonded to the Group VI chalcogen element. The concentration of the Group IV element, by atomic percent, in the corner region is greater than the concentration of the Group IV element, by atomic percent, in the main region, or the concentration of the Group V element, by atomic percent, in the corner region is greater than the concentration of the Group V element, by atomic percent, in the main region.

A memory device includes a first conductive line extending in a first horizontal direction, a second conductive line extending in a second horizontal direction, and a memory cell disposed between the first conductive line and the second conductive line and extending in a vertical direction. The memory cell includes a lower electrode layer, a switching pattern, and an upper electrode layer sequentially stacked on the first conductive line. The switching pattern includes a main region disposed on the lower electrode layer and extending in the vertical direction. The main region includes a pair of first side walls spaced apart from one another in the first horizontal direction and a pair of second walls spaced apart from one another in the second horizontal direction. A pair of first shell regions is disposed on the pair of first side walls of the main region, a pair of second shell regions is disposed on the pair of second side walls of the main region, and a corner region extends in the vertical direction at four corners of the main region. The switching pattern includes a chalcogenide layer including a Group VI chalcogen element of the periodic table and an element of Group IV and an element of Group V of the periodic table, which are chemically bonded to the Group VI chalcogen element. The concentration of the Group IV element, by atomic percent, in the corner region is greater than the concentration of the Group IV element, by atomic percent, in the main region, or the concentration of the Group V element, by atomic percent, in the corner region is greater than the concentration of the Group V element, by atomic percent, in the main region.

A memory device includes a first conductive line extending in a first horizontal direction, a second conductive line extending in a second horizontal direction, a memory cell extending in a vertical direction and disposed between the first conductive line and the second conductive line. The memory cell includes a lower electrode layer, a switching pattern, and an upper electrode layer sequentially stacked on the first conductive line. A first spacer is disposed on the pair of first side walls of the memory cell. A first encapsulation layer is disposed on the first spacer. A second spacer is disposed on the pair of second side walls of the memory cell. A second encapsulation layer is disposed on the second spacer. The switching pattern includes a main region extending in the vertical direction and disposed on the lower electrode layer. The main region includes a pair of first side walls spaced apart from one another in the first horizontal direction and a pair of second walls spaced apart from one another in the second horizontal direction. A pair of first shell regions is disposed on the pair of first side walls of the main region. A pair of second shell regions is disposed on the pair of second side walls of the main region. A corner region extends in the vertical direction at four corners of the main region. The switching pattern includes a chalcogenide layer including a Group VI chalcogen element of the periodic table, and an element of Group IV and an element of Group V of the periodic table, which are chemically bonded to the Group VI chalcogen element. The concentration of the Group IV element, by atomic percent, in the corner region is greater than the concentration of the Group IV element, by atomic percent, in the main region, or the concentration of the Group V element, by atomic percent, in the corner region is greater than the concentration of the Group V element, by atomic percent, in the main region.

### BRIEF DESCRIPTION OF THE DRAWINGS

Embodiments of the present disclosure will be more clearly understood from the following detailed description taken in conjunction with the accompanying drawings in which:

FIG. 1 is a schematic perspective view of a memory device according to some embodiments of the present disclosure;

FIG. 2 is a cross-sectional view of the memory device taken along line A1-A1′ in FIG. 1, and FIG. 3 is a cross-sectional view of the memory device taken along line A2-A2′ in FIG. 1;

FIG. 4 is a plan view of the memory device at a first vertical level LV1 of FIGS. 2 and 3;

FIG. 5 is a schematic diagram and graph showing the voltage-current characteristics of a memory device according to some embodiments of the present disclosure;

FIG. 6 is a schematic diagram for explaining the positive write characteristics of a memory cell according to some embodiments of the present disclosure;

FIGS. 7 and 8 are schematic diagrams and graphs for explaining the read characteristics of a memory cell according to some embodiments of the present disclosure;

FIG. 9 is a schematic diagram for explaining the negative write characteristics of a memory cell according to some embodiments of the present disclosure;

FIGS. 10 and 11 are schematic diagrams and graphs for explaining the read characteristics of a memory cell according to some embodiments of the present disclosure;

FIG. 12 is a graph showing the composition ratio of Group IV elements to Group VI elements in a memory cell according to some embodiments of the present disclosure;

FIG. 13 is a graph showing the composition ratio of Group V elements to Group VI elements in a memory cell according to some embodiments of the present disclosure;

FIG. 14 is a graph showing the threshold voltage distribution of a memory cell according to some embodiments of the present disclosure;

FIG. 15 is a plan view showing a switching pattern of a memory cell according to some embodiments of the present disclosure;

FIGS. 16, 17, 18A, 18B, 19 to 21, 22A, 22B, 23, 24, 25A, and 25B are schematic diagrams showing a method of manufacturing a memory device, according to some embodiments of the present disclosure, in which FIGS. 16, 17, 18A, 19 to 21, 22A, 23, 24, and 25A are cross-sectional views of the memory device taken along lines A1-A1′ and A2-A2′ in FIG. 1, and FIGS. 18B, 22B, and 25B are plan views of the memory device at the first vertical level LV1 in FIGS. 18A, 22A, and 25A, respectively;

FIG. 26 is a configuration diagram of a memory device according to some embodiments of the present disclosure;

FIG. 27 is a configuration diagram of a data processing system including a memory device, according to some embodiments of the present disclosure; and

FIG. 28 is a configuration diagram of a data processing system including a memory device, according to some embodiments of the present disclosure.

### DETAILED DESCRIPTION OF THE EMBODIMENTS

Hereinafter, with reference to the accompanying drawings, embodiments of the inventive concept will be described in detail.

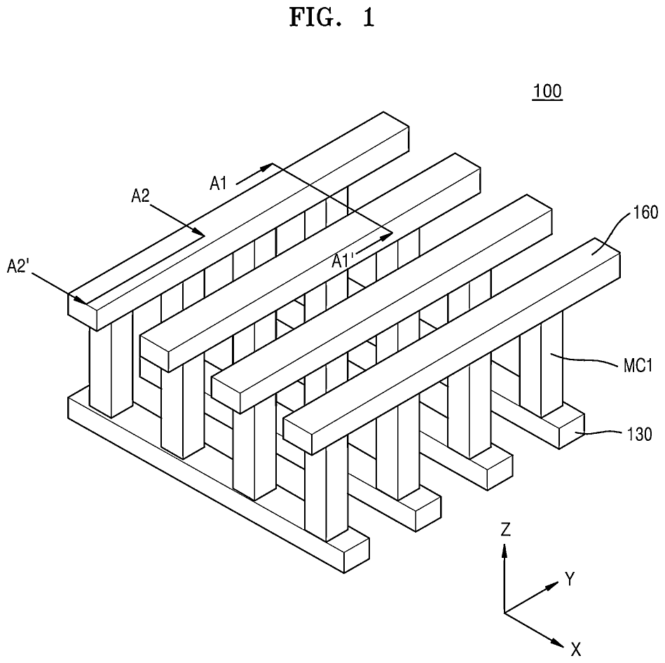

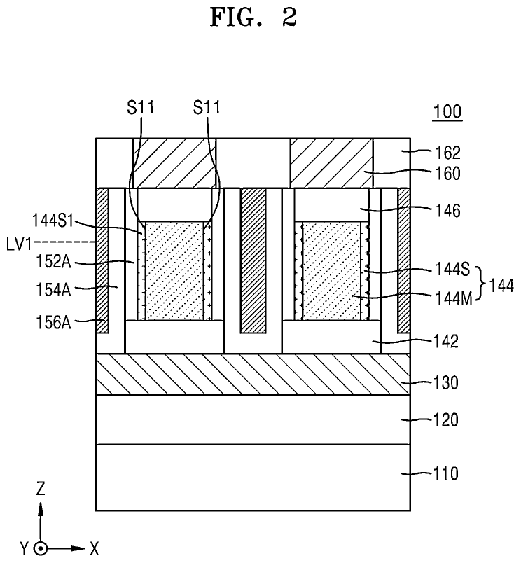

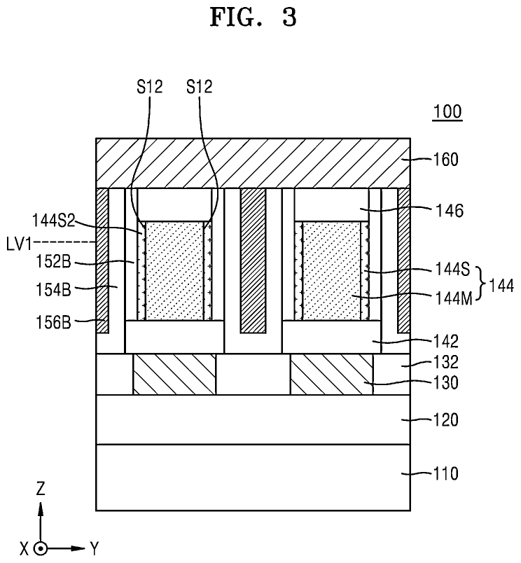

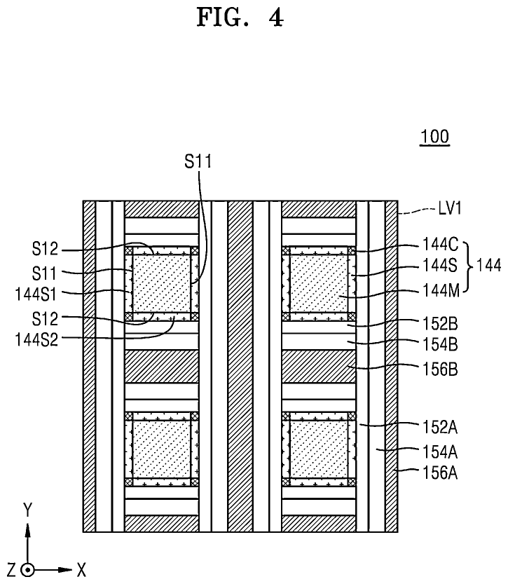

FIG. 1 is a schematic perspective of a memory device 100 according to some embodiments of the present disclosure. FIG. 2 is a cross-sectional view of the memory device taken along line A1-A1′ in FIG. 1, and FIG. 3 is a cross-sectional view of the memory device taken along line A2-A2′ in FIG. 1. FIG. 4 is a plan view of the memory device at a first vertical level LV1 in FIGS. 2 and 3.

Referring to FIGS. 1 to 4, the memory device 100 may include plurality of first conductive lines 130, a plurality of second conductive lines 160 disposed at a vertical level that is higher than the plurality of first conductive lines 130, and a plurality of memory cells MCs located at the points where the plurality of first conductive lines 130 intersect the plurality of second conductive lines 160. The plurality of memory cells MCs may be an array structure spaced apart from each other in a first horizontal direction X and a second horizontal direction Y. The memory device 100 may include a memory cell MC located at an upper portion of a substrate 110 as shown in FIG. 2.

The substrate 110 may include semiconductor materials such as Group IV semiconductor materials, Group III-V semiconductor materials, or Group II-VI semiconductor materials. The Group IV semiconductor material may include, for example, silicon (Si), germanium (Ge), or silicon-germanium (Si—Ge). The Group III-V semiconductor material may include, for example, GaAs, InP, GaP, InAs, InSb, or InGaAs. The Group II-VI semiconductor material may include, for example, ZnTe or CdS.

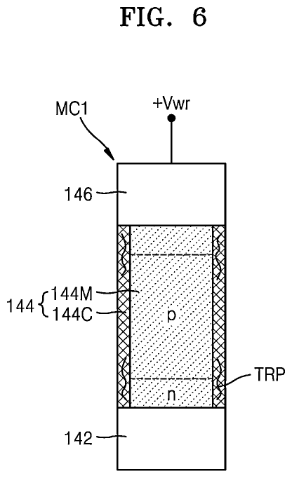

A lower structure 120 may be disposed between the substrate 110 and the plurality of first conductive lines 130. The lower structure 120 may include an insulation material that electrically insulates the plurality of first conductive lines 130 from the substrate 110. In some embodiments of the present disclosure, the lower structure 120 may include a peripheral circuit PTR (see FIG. 6) for driving the plurality of memory cells MCs, and for example, may further include a wiring structure for electrically connect the peripheral circuit PTR placed on the substrate 110 to the plurality of first conductive lines 130 and the plurality of second conductive lines 160.

The plurality of first conductive lines 130 may extend parallel to each other in the first horizontal direction X, and the plurality of second conductive lines 160 may extend parallel to each other in the second horizontal direction Y that intersects the first horizontal direction X at a vertical level that is higher than the plurality of first conductive lines 130. Here, the vertical level may be defined based on a top surface of the substrate 110. For example, the expression that the plurality of second conductive lines 160 are disposed at the vertical level that is higher than the plurality of first conductive lines 130 means that the distance from the plurality of second conductive lines 160 to the top surface of the substrate 110 is greater than the distance from the plurality of first conductive lines 130 to the top surface of the substrate 110.

In some embodiments of the present disclosure, the plurality of first conductive lines 130 may be referred to as word lines, and the plurality of second conductive lines 160 may be referred to as bit lines.

In some embodiments of the present disclosure, the plurality of first conductive lines 130 and the plurality of second conductive lines 160 may each include a metal, conductive metal nitrides, conductive metal oxides, or combinations thereof. In some examples, the plurality of first conductive lines 130 and the plurality of second conductive lines 160 may each include W, WN, Au, Ag, Cu, A1, TiAlN, Ir, Pt, Pd, Ru, Zr, Rh, Ni, Co, Cr, Sn, Zn, ITO, alloys thereof, or combinations thereof. In some examples, the plurality of first conductive lines 130 and the plurality of second conductive lines 160 may each include a metal film and a conductive barrier layer that covers at least a part of the metal film. The conductive barrier layer may include, for example, Ti, TiN, Ta, TaN, WSiN, WN, or combinations thereof.

The plurality of memory cells MC1 may be disposed between the plurality of first conductive lines 130 and the plurality of second conductive lines 160, and may extend to a predetermined height in a vertical direction Z that is perpendicular to the top surface of the substrate 110. For example, the plurality of first conductive lines 130 may extend in the first direction X at the first vertical level, and the plurality of second conductive lines 160 may extend in the second direction Y at the second vertical level that is different from the first vertical level. The plurality of memory cells MC1 may be disposed at cross points or overlap positions of the plurality of first conductive lines 130 and the plurality of second conductive lines 160 in the plan view. The plurality of memory cells MC1 may be disposed on the plurality of first conductive lines 130 and below the plurality of second conductive lines 160, and may be spaced apart from one another in the first direction X and the second direction Y. This arrangement of the plurality of memory cells MC1 may be referred to as a cross point type configuration. For example, the memory device 100 disclosed in FIGS. 1 to 4 may have the cross point type configuration of one layer stack in which the plurality of memory cells MC1 are disposed at the same vertical level.

The plurality of memory cells MC1 may include a lower electrode layer 142, a switching pattern 144, and an upper electrode layer 146 sequentially disposed in the vertical direction Z on the plurality of first conductive lines 130.

The lower electrode layer 142 may include a metal, conductive metal nitrides, conductive metal oxides, or carbon-based materials. For example, the lower electrode layer 142 may include a carbon electrode or a carbon nitride electrode.

The switching pattern 144 may include a material layer of which electrical resistance may vary depending on the magnitude of the voltage applied on both ends of the switching pattern 144. The switching pattern 144 may include a material having ovonic threshold switching (OTS) characteristics. In some embodiments of the present disclosure, when a voltage that is less than the threshold voltage is applied to the switching pattern 144, the switching pattern 144 may be in a high resistance state in which little or no current flows. When the voltage that is greater than the threshold voltage is applied to the switching pattern 144, the switching pattern 144 may be in a low resistance state in which the current may flow.

The switching pattern 144 may be a selector only memory element, where the selector only memory element may indicate a device component that performs a switching function component and a memory storage component at the same time. For example, the switching pattern 144 may include a chalcogenide material capable of a bidirectional write operation, and the chalcogenide material may include a material whose threshold voltage changes in the bidirectional write operation.

The switching pattern 144 may be composed of a single film. In some embodiments of the present disclosure, the switching pattern 144 may include a chalcogenide layer including a Group VI chalcogen element of the periodic table, and an element of Group IV and an element of Group V of the periodic table that are chemically bonded to the Group VI chalcogen element. The Group VI chalcogen element may include Te, Se, and/or S. The Group V element may include As, Sb, and/or P. The Group IV element may include Si and/or Ge.

In some embodiments of the present disclosure, the switching pattern 144 may further include a doped element of Group III of the periodic table that is doped into the switching pattern 144 in addition to the previous elements. The doped element of Group III may include In, Ga, and/or Al.

In some embodiments of the present disclosure, the switching pattern 144 may include a main region 144M, a shell region 144S, and a corner region 144C.

The main region 144M may extend in the vertical direction Z on the lower electrode layer 142 and may have a square or a rectangular cross-sectional shapes in the plan view. The main region 144M may have a pair of first side walls S11 spaced apart from one another in the first horizontal direction X and a pair of second side walls S12 spaced apart from one another in the second horizontal direction Y. The pair of first side walls S11 may be spaced apart from each other in the first horizontal direction X and extend in the second horizontal direction Y, and the pair of second side walls S12 may be spaced apart from each other in the second horizontal direction Y and extend in the first horizontal direction X.

The shell region 144S may be disposed on the pair of first side walls S11 and the pair of second side walls S12 of the main region 144M. The shell region 144S may be extended in the vertical direction Z, while covering substantially the entire surface of the pair of first side walls S11 and the pair of second side walls S12. For example, as shown in FIG. 4, a pair of first shell regions 144S1 may be disposed on the pair of first side walls S11 of the main region 144M and a pair of second shell regions 144S2 may be disposed on the pair of second side walls S12 of the main region 144M.

The corner region 144C may be disposed at four corners of the main region 144M having a square or rectangular plane cross-sectional shape and may extend in the vertical direction Z. For example, four corner regions 144C may be spaced apart from each other at four corners of one main region 144M, and any one corner region 144C may be located at a point where one of the pair of first side walls S11 and one of the pair of second side walls S12 of the main region 144M meet. For example, two of the four corner regions 144C may be spaced apart from one another in a first diagonal direction with one main region 144M therebetween, and the other two of the four corner regions 144C may be spaced apart from one another in a second diagonal direction that intersects the first diagonal direction with one main region 144M therebetween.

As shown in FIG. 4, one corner region 144C may be disposed between one first shell region 144S1 of the pair of first shell regions 144S1 and one second shell region 144S2 of the pair of second shell regions 144S2, and may contact the one first shell region 144S1 of the pair of first shell regions 144S1 and the one second shell region 144S2 of the pair of second shell regions 144S2.

The main region 144M, the shell regions 144S, and the corner regions 144C may extend in the vertical direction Z across the entire height of the switching pattern 144. For example, FIG. 4 is shown as a planar shape of the switching pattern 144 observed at the first vertical level LV1, and the planar shape taken at any vertical level over the entire height of the switching pattern 144 may also be substantially the same or similar to that shown in FIG. 4.

In some embodiments of the present disclosure, the concentration of Group IV elements or Group V elements, by atomic percent, contained in the corner region 144C may be different from the concentration of Group IV elements or Group V elements, by atomic percent, contained in the main region 144M. For example, as shown in FIG. 4, when comparing the composition of the chalcogenide layer at a part of the corner region 144C with the composition of the chalcogenide layer at a part of the main region 144M disposed at the same vertical level, the concentration of Group IV elements, by atomic percent, in the corner region 144C may be greater than the concentration of Group IV elements, by atomic percent, in the main region 144M, and/or the concentration of Group V elements, by atomic percent, in the corner region 144C may be greater than the concentration of Group V elements, by atomic percent, in the main region 144M.

In some embodiments of the present disclosure, the concentration of Group IV elements or Group V elements, by atomic percent, contained in the shell region 144S may be different from the concentration of Group IV elements or Group V elements, by atomic percent, contained in the main region 144M. For example, as shown in FIG. 4, when comparing the composition of the chalcogenide layer at a part of the shell region 144S with the composition of the chalcogenide layer at a part of the main region 144M disposed at the same vertical level, the concentration of Group IV elements, by atomic percent, in the shell region 144S may be greater than the concentration of Group IV elements, by atomic percent, in the main region 144M, and/or the concentration of Group V elements, by atomic percent, in the shell region 144S may be greater than the concentration of Group V elements, by atomic percent, in the main region 144M.

In some embodiments of the present disclosure, the concentration of Group IV elements or Group V elements, by atomic percent, contained in the shell region 144S may be different from the concentration of Group IV elements or Group V elements, by atomic percent, contained in the corner region 144C. For example, as shown in FIG. 4, when comparing the composition of the chalcogenide layer at a part of the shell region 144S with the composition of the chalcogenide layer at a part of the corner region 144C disposed at the same vertical level, the concentration of Group IV elements, by atomic percent, in the shell region 144S may be less than the concentration of Group IV elements, by atomic percent, in the corner region 144C, and/or the concentration of Group V elements, by atomic percent, in the shell region 144S may be less than the concentration of Group V elements, by atomic percent, in the corner region 144C.

In some embodiments of the present disclosure, the main region 144M included in the switching pattern 144 may include Group IV elements of 15 to 25 atomic % (at %), Group V elements of 20 to 30 at %, and Group VI elements of 45 to 65 at %. The corner region 144C included in the switching pattern 144 may include Group IV elements of 10 to 20 at %, Group V elements of 25 to 40 at %, and Group VI elements of 40 to 65 at %.

In some embodiments of the present disclosure, the ratio of the concentration of Group VI elements, by atomic percent, to the concentration of the Group IV elements, by atomic percent, in the corner region 144C included in the switching pattern 144 may be greater than 0.5 and less than 1. In some embodiments of the present disclosure, the ratio of the concentration of Group VI elements, by atomic percent, to the concentration of the Group V elements, by atomic percent, in the corner region 144C included in the switching pattern 144 may be greater than 0.6 and less than 1.4.

The upper electrode layer 146 may include a metal, conductive metal nitrides, conductive metal oxides, or carbon-based materials. For example, the upper electrode layer 146 may include a carbon electrode or a carbon nitride electrode.

A first insulating layer 132 that fills a space between the plurality of first conductive lines 130 may be disposed on the lower structure 120. In addition, a second insulating layer 162 that fills a space between the plurality of second conductive lines 160 may be disposed. The first insulating layer 132 and the second insulating layer 134 may include silicon oxide.

A first spacer 152A may be disposed on side walls of the pair of first shell regions 144S1 of the switching pattern 144. The first spacer 152A may extend from the side walls of the first shell regions 144S1 to side walls of the upper electrode layer 146, and bottom surfaces of the first spacer 152A may be placed on a top surface of the lower electrode layer 142. For example, one side wall of the first spacer 152A may contact the side wall of the first shell region 144S1 and the side wall of the upper electrode layer 146.

A first encapsulation layer 154A may be disposed on the other side wall of the first spacer 152A. The first encapsulation layer 154A may extend in the vertical direction Z over the entire height of the upper electrode layer 146, the switching pattern 144, and the lower electrode layer 142, and portions of the first encapsulation layer 154A may be disposed on the upper surface of the first conductive line 130 and the first insulating layer 132. A first buried insulating layer 156A may be disposed on the side wall of the first encapsulation layer 154A.

A second spacer 152B may be disposed on side walls of the pair of second shell regions 144S2 of the switching pattern 144. The second spacer 152B may extend from the side walls of the second shell regions 144S2 onto side walls of the upper electrode layer 146, and bottom surfaces of the second spacer 152B may be placed on the top surface of the lower electrode layer 142. For example, one side wall of the second spacer 152B may contact the side wall of the second shell region 144S2 and the side wall of the upper electrode layer 146.

A second encapsulation layer 154B may be disposed on the other side wall of the second spacer 152B. The second encapsulation layer 154B may extend in the vertical direction Z over the entire height of the upper electrode layer 146, the switching pattern 144, and the lower electrode layer 142, and portions of the second encapsulation layer 154B may be disposed on the upper surface of the first conductive line 130 and the first insulating layer 132. A second buried insulating layer 156B may be disposed on the side wall of the second encapsulation layer 154B.

In embodiments of the present disclosure, the first spacer 152A, the first encapsulation layer 154A, the first buried insulating layer 156A, the second spacer 152B, the second encapsulation layer 154B, and the second buried insulating layer 156B may each include silicon nitride, silicon oxide, silicon oxynitride, and/or a low-k dielectric material. As used herein, the term “low-k” may be understood to mean a material having a dielectric constant that is less than or equal to that of silicon oxide. In some embodiments of the present disclosure, the first spacer 152A and the second spacer 152B may include silicon nitride, and the first encapsulation layer 154A and the second encapsulation layer 154B may include silicon nitride, and the first buried insulating layer 156A and the second buried insulating layer 156B may include silicon oxide. In some other embodiments of the present disclosure, the first spacer 152A and the second spacer 152B may include silicon nitride, and the first encapsulation layer 154A and the second encapsulation layer 154B may include silicon nitride, and the first buried insulating layer 156A and the second buried insulating layer 156B may include low-k dielectric material. In some other embodiments of the present disclosure, the first buried insulating layer 156A and the second buried insulating layer 156B may include an air gap or a void therein.

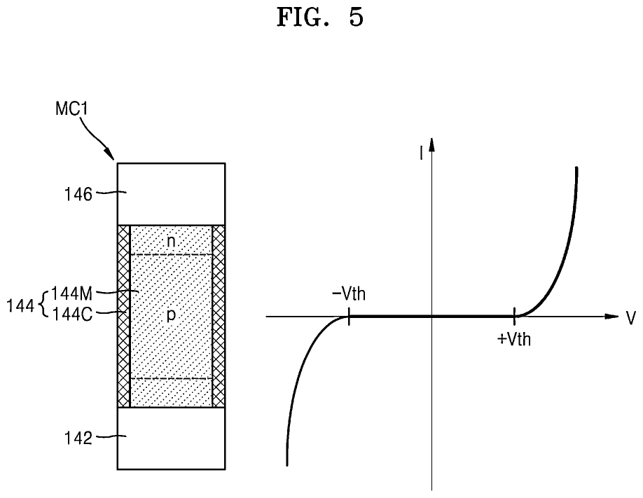

FIG. 5 is a schematic diagram and graph showing voltage-current characteristics of the memory device 100 according to some embodiments of the present disclosure.

Referring to FIG. 5, the memory cell MC1 described with reference to FIGS. 1 to 4 may show a bidirectional threshold voltage characteristic as shown in FIG. 5. For example, when the positive voltage is applied to the memory cell MC1, switching characteristics may appear in the positive threshold voltage +Vth. In addition, when the negative voltage is applied to the memory cell MC1, switching characteristics may appear in the negative threshold voltage −Vth.

For example, in the memory device 100 described with respect to FIGS. 1 to 4, the switching pattern 144 (e.g., the main region 144M included in the switching pattern 144) between the lower electrode layer 142 and the upper electrode layer 146 may have the concentration gradient of Group IV elements, the concentration gradient of Group V elements, and/or the concentration gradient of Group VI elements of a chalcogenide material in the vertical direction, and accordingly, the switching pattern 144 may have a structure in which an n-type semiconductor, a p-type semiconductor, and an n-type semiconductor are arranged in series in the vertical direction, so the switching pattern 144 may exhibit switching characteristics capable of bidirectional rectification.

FIG. 6 is a schematic diagram for illustrating positive writing characteristics of a memory cell according to some embodiments of the present disclosure.

Referring to FIG. 6, a positive write voltage +Vwr may be applied to the upper electrode layer 146 to perform a set operation. When the positive write voltage +Vwr is applied to the upper electrode layer 146, the concentration gradient of Group IV elements, the concentration gradient of Group V elements, and/or Group VI group elements in the main region 144M of the switching pattern 144 may remain the same without changing. In addition, when the positive write voltage +Vwr is applied to the upper electrode layer 146, there is no change in the microstructure of the main region 144M of the switching pattern 144 and an amorphous structure may be maintained.

On the other hand, when the positive write voltage +Vwr is applied to the upper electrode layer 146, the same type of elements may be locally aligned in the corner region 144C. For example, Group IV elements such as germanium or Group V elements such as arsenic may be aligned in the corner region 144C, and therefore, a localized electrical path TRP by trap sites may be generated within the corner region 144C.

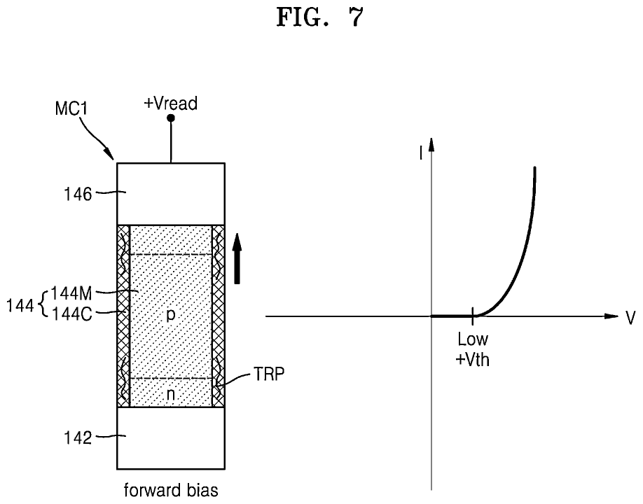

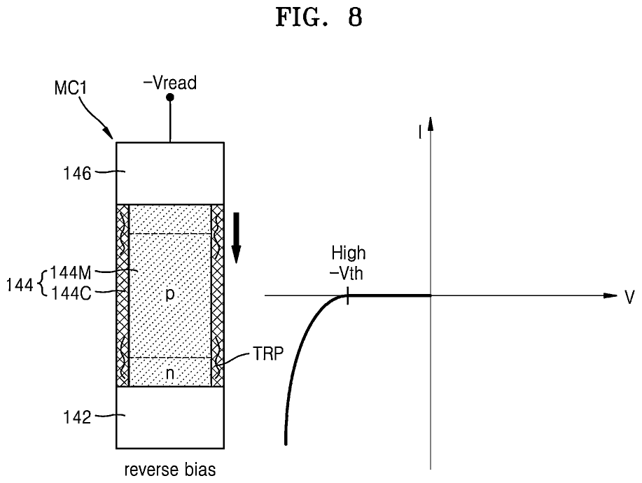

FIGS. 7 and 8 are schematic diagrams and graphs for illustrating read characteristics of a memory cell according to some embodiments of the present disclosure.

Referring to FIG. 7, the positive read voltage +Vread may be applied to the upper electrode layer 146 of the memory cell MC1 on which the set operation has been performed by applying the positive write voltage +Vwr (see FIG. 6). In this case, the forward bias may be applied to the switching pattern 144 and the built-in potential of the switching pattern 144 may decrease, so the memory cell MC1 may exhibit switching characteristics at low positive threshold voltage Low +Vth. Herein, the low positive threshold voltage Low +Vth means that the threshold voltage has the positive value and the magnitude or absolute value of the threshold voltage is relatively small.

Referring to FIG. 8, the negative read voltage −Vread may be applied to the upper electrode layer 146 of the memory cell MC1 on which the set operation has been performed by applying the positive write voltage +Vwr (see FIG. 6). In this case, the reverse bias may be applied to the switching pattern 144 and the built-in potential of the switching pattern 144 may increase, so the memory cell MC1 may exhibit switching characteristics at high negative threshold voltage High −Vth. Herein, the high negative threshold voltage High −Vth means that the threshold voltage has the negative value and the magnitude or absolute value of the threshold voltage is relatively large.

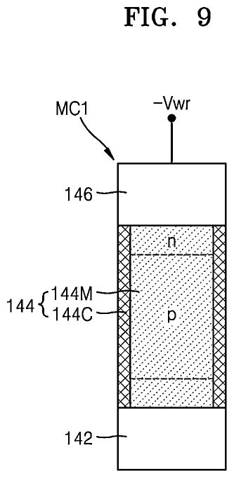

FIG. 9 is a schematic diagram for illustrating negative write characteristics of a memory cell according to some embodiments of the present disclosure.

Referring to FIG. 9, the negative write voltage −Vwr may be applied to the upper electrode layer 146 to perform a reset operation. When the negative write voltage −Vwr is applied to the upper electrode layer 146, the concentration gradient of Group IV elements, the concentration gradient of Group V elements, and/or Group VI group elements in the main region 144M of the switching pattern 144 may remain the same without changing. In addition, when the negative write voltage −Vwr is applied to the upper electrode layer 146, there is no change in the microstructure of the main region 144M of the switching pattern 144 and the amorphous structure may be maintained.

On the other hand, when the negative write voltage −Vwr is applied to the upper electrode layer 146, the same type of elements may be locally relocated or dispersed in the corner region 144C. For example, Group IV elements such as germanium or Group V elements such as arsenic may be relocated or dispersed in the corner region 144C, and therefore, a localized switching path by trap sites may be removed or lost within the corner region 144C.

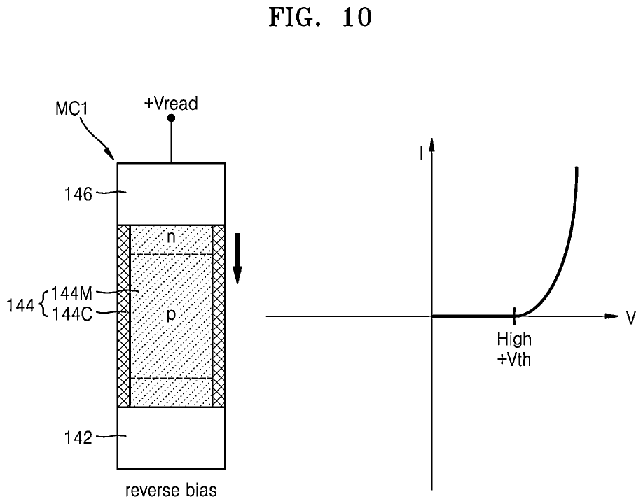

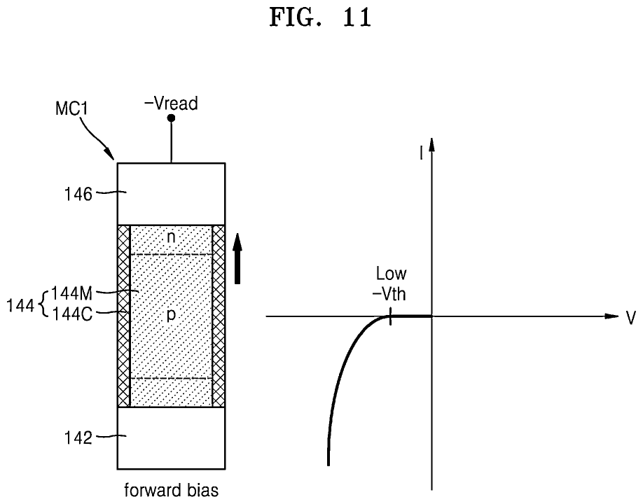

FIGS. 10 and 11 are schematic diagrams and graphs for illustrating read characteristics of a memory cell according to some embodiments of the present disclosure.

Referring to FIG. 10, the positive read voltage +Vread may be applied to the upper electrode layer 146 of the memory cell MC1 on which the reset operation has been performed by applying the negative write voltage −Vwr. In this case, the reverse bias may be applied to the switching pattern 144 and the built-in potential of the switching pattern 144 may increase, so the memory cell MC1 may exhibit switching characteristics at high positive threshold voltage High +Vth. Herein, the high positive threshold voltage High +Vth means that the threshold voltage has the positive value and the magnitude or absolute value of the threshold voltage is relatively large.

Referring to FIG. 11, the negative read voltage −Vread may be applied to the upper electrode layer 146 of the memory cell MC1 on which the reset operation has been performed by applying the negative write voltage −Vwr. In this case, the forward bias may be applied to the switching pattern 144 and the built-in potential of the switching pattern 144 may decrease, so the memory cell MC1 may exhibit switching characteristics at low negative threshold voltage Low-Vth. Herein, the low negative threshold voltage Low-Vth means that the threshold voltage has the negative value and the magnitude or absolute value of the threshold voltage is relatively small.

As described with reference to FIGS. 5 to 11, the switching pattern 144 may function as a selector-only memory element having bidirectional rectification characteristics, and the same type of elements may be locally aligned through the corner region 144C of the switching pattern 144 and the trap sites may be connected to each other, so the threshold voltage distribution of the memory cell MC1 may be reduced or the window of the threshold voltage may be narrowed.

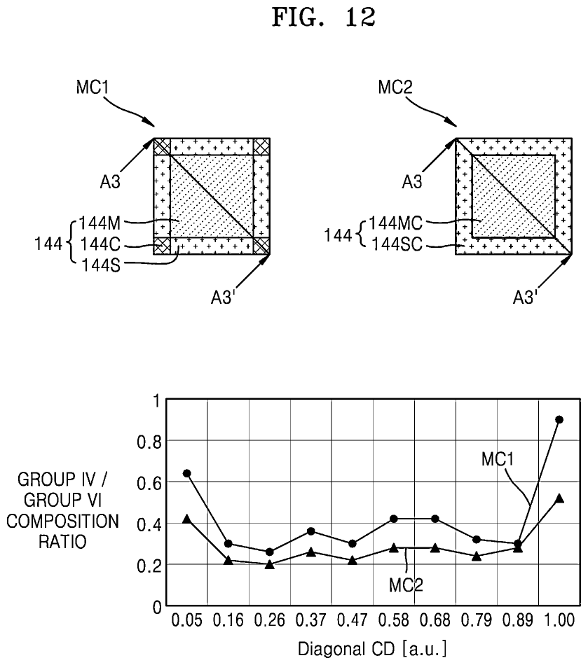

FIG. 12 is a graph showing the composition ratio of Group IV elements to Group VI elements in a memory cell according to some embodiments of the present disclosure.

Referring to FIG. 12, the composition ratios of Group IV elements to Group VI elements scanned along lines A3-A3′ in the diagonal direction of the switching pattern 144 in the memory cell MC1, according to some embodiments of the present disclosure, and a memory cell MC2 according to the comparative example, respectively, is shown.

According to the memory cell MC1 according to some embodiments of the present disclosure, the composition ratio of Group IV elements to Group VI elements, by atomic percent, in the corner region 144C may be relatively large, for example, with a value of 0.5 or more and 1 or less, and the composition ratio of Group IV elements to Group VI elements in the main region 144M may be relatively small.

On the other hand, the memory cell MC2, according to the comparative example, has a structure in which a corner region is not formed and a shell region 144SC surrounds the entire side wall of a main region 144MC. According to the memory cell MC2, according to the comparative example, the composition ratio of the composition ratio of Group IV elements to Group VI elements in the shell region 144SC may be greater than the composition ratio of Group IV elements to Group VI elements in the main region 144MC. However, the composition ratio of Group IV elements to Group VI elements in the shell region 140SC of the memory cell MC2 of the comparative example may be less than the composition ratio of Group IV elements to Group VI elements in the corner region 144C of the memory cell MC1 of the embodiments of the present disclosure.

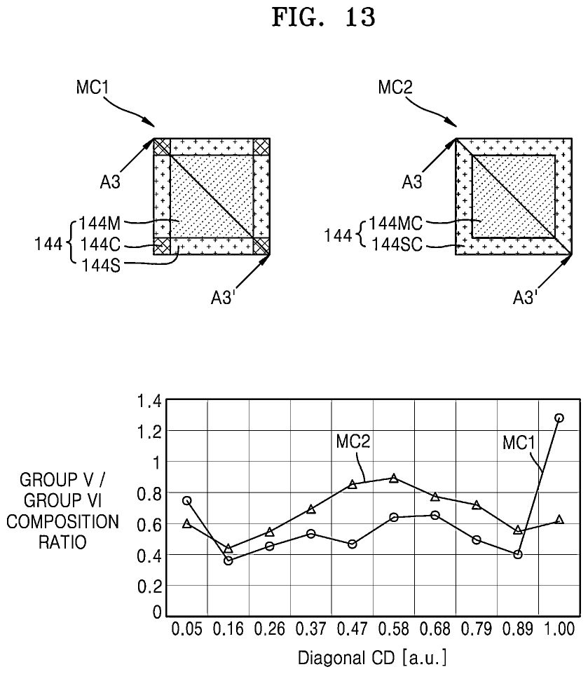

FIG. 13 is a graph showing the composition ratio of Group V elements to Group VI elements in a memory cell according to some embodiments of the present disclosure.

Referring to FIG. 13, the composition ratios of Group V elements to Group VI elements scanned along lines A3-A3′ in the diagonal direction of the switching pattern 144 in the memory cell MC1, according to some embodiments of the present disclosure, and the memory cell MC2, according to the comparative example, respectively, is shown.

According to the memory cell MC1, according to some embodiments of the present disclosure, the composition ratio of Group V elements to Group VI elements, by atomic percent, in the corner region 144C may be relatively large, for example, with a value of 0.6 or more and 1.4 or less, and the composition ratio of Group V elements to Group VI elements in the main region 144M may be relatively small.

On the other hand, the memory cell MC2, according to the comparative example, has a structure in which a corner region is not formed and a shell region 144SC surrounds the entire side wall of a main region 144MC. According to the memory cell MC2, according to the comparative example, the composition ratio of the composition ratio of Group V elements to Group VI elements in the shell region 144SC may be less than the composition ratio of Group V elements to Group VI elements in the main region 144MC. In addition, the composition ratio of Group V elements to Group VI elements in the shell region 140SC of the memory cell MC2 of the comparative example may be less than the composition ratio of Group V elements to Group VI elements in the corner region 144C of the memory cell MC1 of the embodiments of the present disclosure.

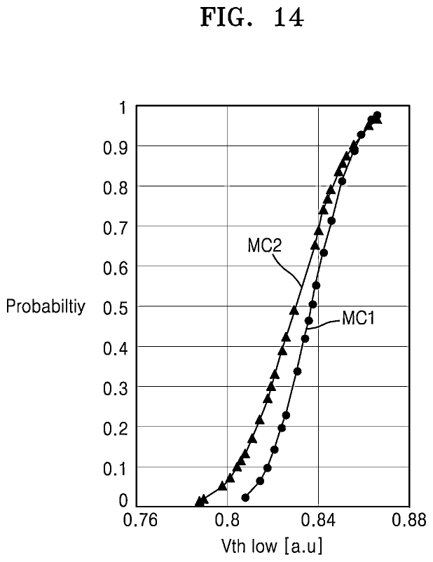

FIG. 14 is a graph showing the threshold voltage distribution of a memory cell according to some embodiments of the present disclosure.

Referring to FIG. 14, the threshold voltage distributions of the memory cell MC1, according to some embodiments of the present disclosure, and the memory cell MC2, according to the comparative example, are shown, respectively. As shown in FIGS. 12 and 13, the memory cell MC2, according to the comparative example, has a structure in which the corner region is not formed and the shell region 144SC surrounds the entire side wall of the main region 144MC.

As shown in FIG. 14, it may be confirmed that the threshold voltage distribution of the memory cell MC1, according to some embodiments of the present disclosure, is less (narrower threshold voltage window) than that of the memory cell MC2, according to the comparative example.

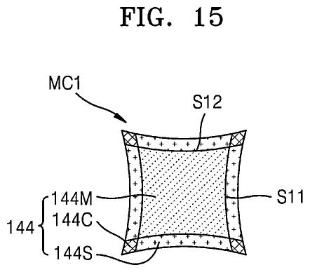

FIG. 15 is a plan view showing a switching pattern 144 of a memory cell MC1 according to some embodiments of the present disclosure.

Referring to FIG. 15, the switching pattern 140 may have curved side walls that are recessed inward. For example, both a pair of first side walls S11 and a pair of second side walls S12 of the main region 144M may have curved shapes that are recessed inward, for example, in a direction toward the main region 144M. In addition, the shell region 144S disposed on the pair of first side walls S11 and the pair of second side walls S12 of the main region 144M may also have outer walls of curved shape that conform to the curved shapes of the pairs of first and second side walls S11 and S12.

In embodiments of the present disclosure, in a patterning process of forming the switching pattern 140, central parts of the side walls of the switching pattern 140 may be more exposed to the etching atmosphere than edges of the side walls of the switching pattern 140, so the central parts of the side walls of the switching pattern 140 may be recessed inward. In this case, as shown in FIG. 15, the switching pattern 140 may have the curved side walls that is recessed inward.

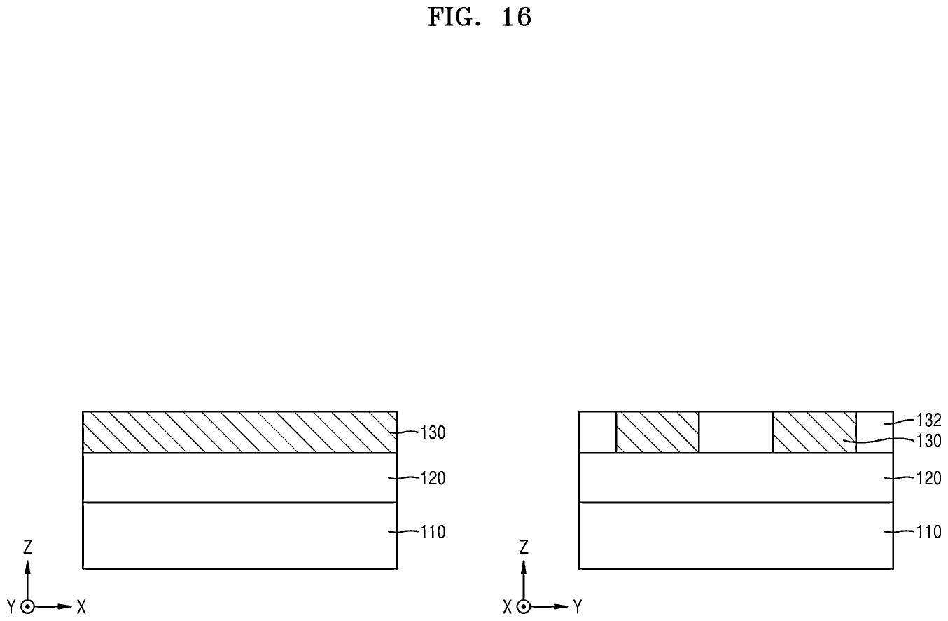

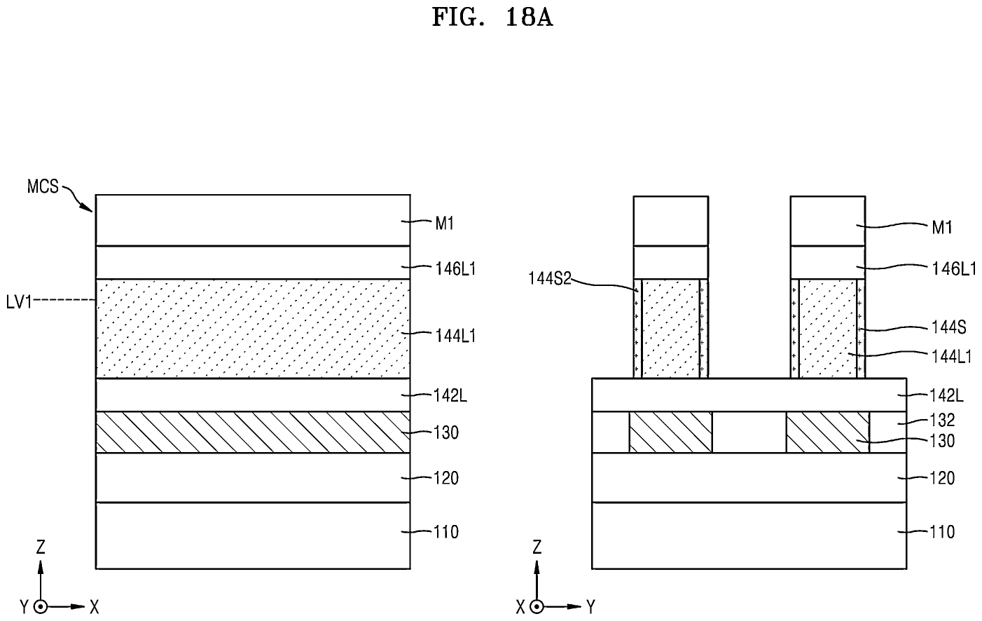

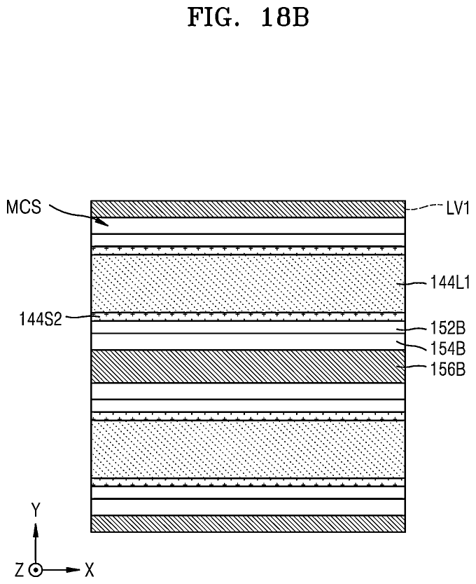

FIGS. 16, 17, 18A, 18B, 19 to 21, 22A, 22B, 23, 24, 25A, and 25B are schematic diagrams showing a method of manufacturing the memory device 100, according to some embodiments of the present disclosure. FIGS. 16, 17, 18A, 19 to 21, 22A, 23, 24, and 25A are cross-sectional views of the memory device 100 taken along lines A1-A1′ and A2-A2′ in FIG. 1, and FIGS. 18B, 22B, and 25B are plan views of the memory device 100 at a first vertical level LV1 in FIGS. 18A, 22A, and 25A, respectively.

Referring to FIG. 16, a lower structure 120 may be formed on a substrate 110. A first conductive layer may be formed on the lower structure 120 and the first conductive layer may be patterning to form a plurality of first conductive lines 130. Thereafter, an insulating layer may be formed on the plurality of first conductive lines 130 and the lower structure 120, and a top surface of the insulating layer may be planarized until a top surface of the plurality of first conductive lines 130 is exposed, thereby forming a first insulating layer 132.

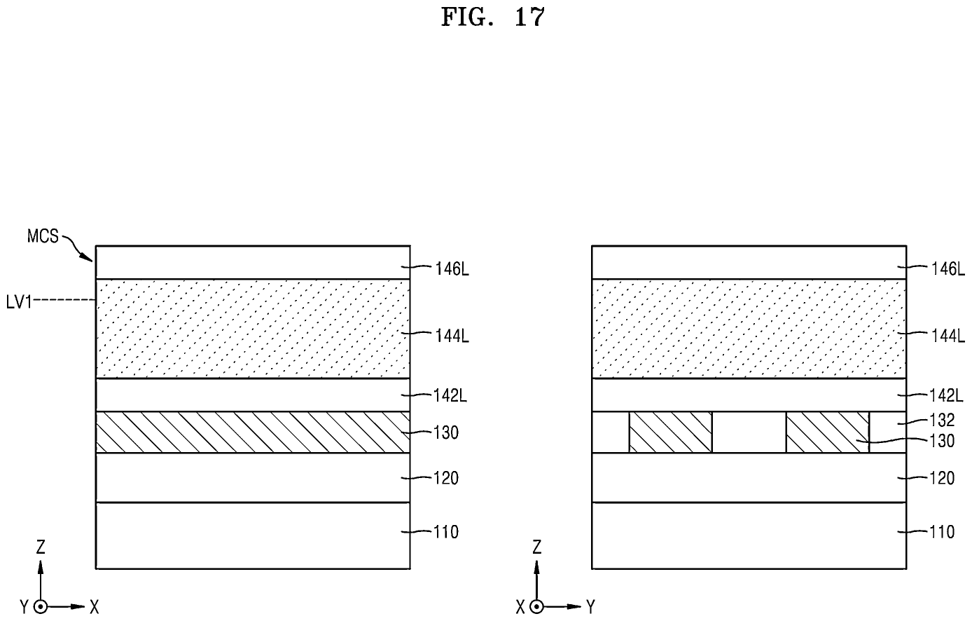

Referring to FIG. 17, a memory cell stack MCS may be formed on the plurality of first conductive lines 130 and the first insulating layer 132, in which the memory cell stack MCS may sequentially include a lower electrode material layer 142L, a switching material layer 144L, and an upper electrode material layer 146L.

In embodiments of the present disclosure, a process of forming the switching material layer 142L may include a physical vapor deposition (PVD) process and/or a chemical vapor deposition (CVD) process.

Referring to FIGS. 18A and 18B, a first mask pattern M1 may be formed on the memory cell stack MCS, and then the first mask pattern M1 may be used as an etch mask to pattern a portion of the memory cell stack MCS. At this time, the switching material layer 144L and the upper electrode material layer 146L may be patterned to form a switching material line 144L1 and an upper electrode line 146L1.

In embodiments of the present disclosure, the first mask pattern M1 may be a pattern of line shape that may extend in the first horizontal direction X and may be spaced apart from one another in the second horizontal direction Y.

In embodiments of the present disclosure, an etching process using a reactive gas containing hydrogen may be used in the process that patterns the portion of the memory cell stack MCS. For example, the etching process may be a reactive ion etching process. In some embodiments of the present disclosure, the reactive gas containing hydrogen may include CH₄, H₂, etc. In some embodiments of the present disclosure, the reactive gas containing hydrogen may have an etching selectivity (having relatively high etching rate) for Group VI elements contained in the chalcogenide material layer.

As the switching material line 144L1 is formed, a shell region 144S may be formed at the side wall of the switching material line 144L1 with a predetermined depth. For example, as the switching material line 144L1 extends in the first horizontal direction X, a pair of second shell regions 144S2 may be formed on both side walls of the switching material line 144L1.

The shell region 144S may be a region where some of Group VI elements, such as selenium (Sc), has been removed from the side wall of the switching material line 144L1 by the reactive ion etching process having a relatively high etching rate for Group VI elements. The shell region 144S may indicate the region where the composition of Group VI elements changed in comparison with an internal region (bulk region) of the switching material line 144L1.

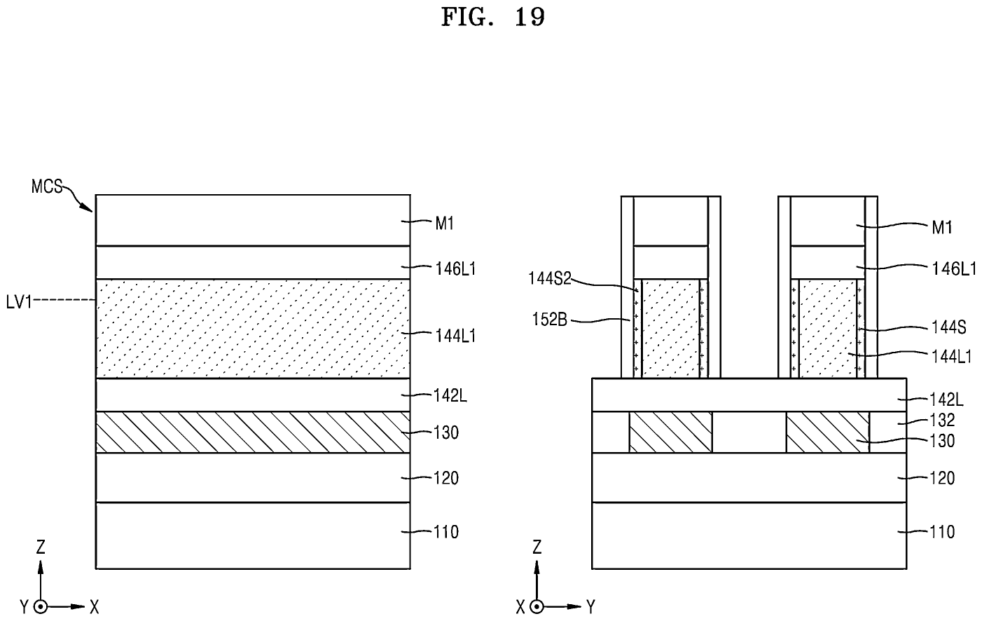

Referring to FIG. 19, a second spacer 152B may be formed on the side walls of the switching material line 144L1 and the upper electrode line 146L1. The second spacer 152B may be conformally formed with a relatively thin thickness, on the side walls of the switching material line 144L1, the upper electrode line 146L1, and the first mask pattern M1.

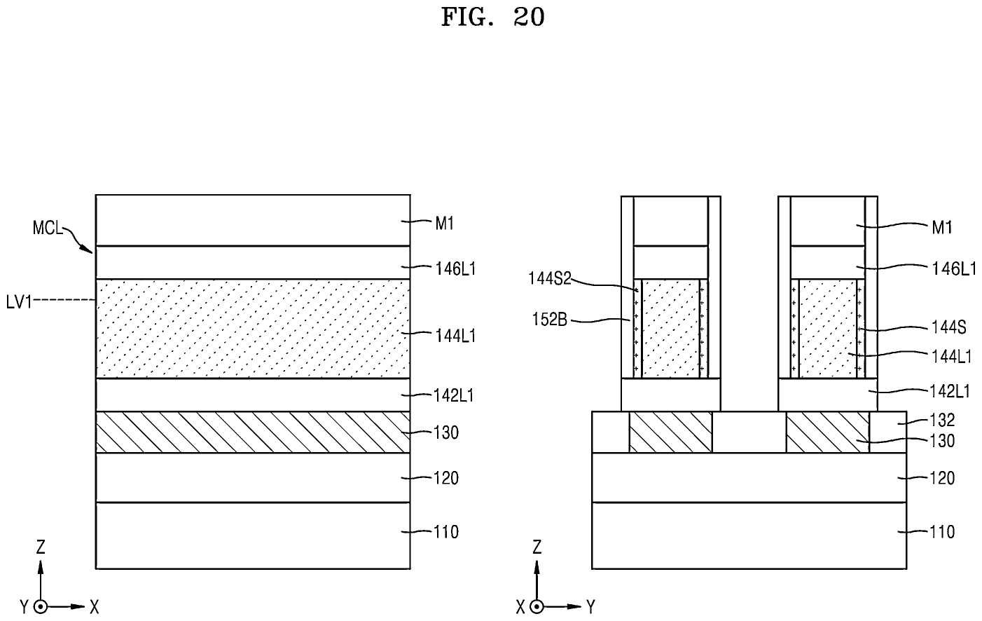

Referring to FIG. 20, lower electrode lines 142L1 may be formed by patterning the lower electrode material layer 142L using the first mask pattern M1 and the second spacer 152B as an etch mask.

In embodiments of the present disclosure, etching gases containing oxygen may be used in the process of forming the lower electrode lines 142L1. In the etching atmosphere for forming the lower electrode lines 142L1, the side wall of the switching material line 144L1 may be covered by the second spacer 152B and thus might not be exposed to the etching atmosphere.

Herein, the lower electrode line 142L1, the switching material line 144L1, and the upper electrode line 146L1 may be referred to as a memory cell line MCL. The memory cell lines MCL may extend in the first horizontal direction X and may be spaced apart from each other in the second horizontal direction Y.

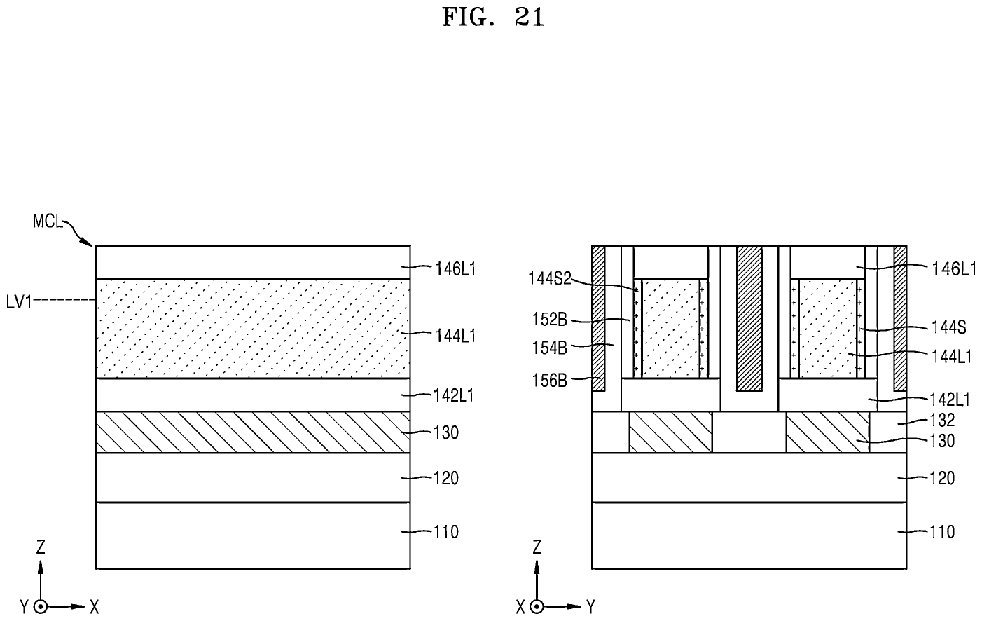

Referring to FIG. 21, second encapsulation layers 154B may be formed on the side walls of the lower electrode lines 142L1, the switching material lines 144L1, and the upper electrode lines 146L1 (i.e., on the side walls of the memory cell lines MCL). Thereafter, second buried insulating layers 156B may be formed on the second encapsulation layers 154B to fill spaces between adjacent memory cell lines MCL. The first mask pattern M1 may also be removed in a process of planarizing upper portions of the second buried insulating layers 156B.

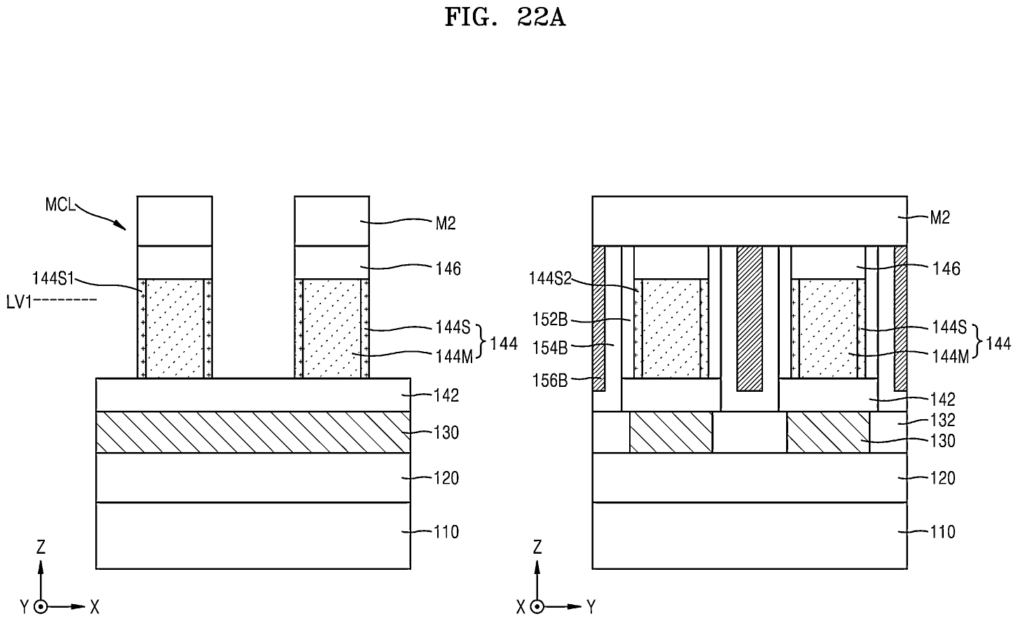

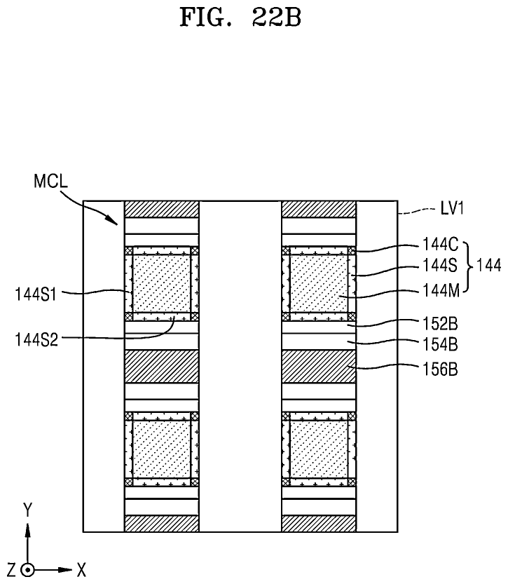

Referring to FIGS. 22A and 22B, a second mask pattern M2 may be formed on the memory cell line MCL, and then the second mask pattern M2 may be used as an etch mask to pattern a portion of the memory cell line MCL. At this time, the switching material line 144L1 and the upper electrode material line 146L1 may be patterned to form a switching pattern 144 and an upper electrode layer 146.

In embodiments of the present disclosure, the second mask pattern M2 may be a pattern of line shape that may extend in the second horizontal direction Y and may be spaced apart from one another in the first horizontal direction X.

In embodiments of the present disclosure, an etching process using a reactive gas containing hydrogen may be used in the process that patterns a portion of the memory cell line MCL. For example, the etching process may be the reactive ion etching process. In some embodiments of the present disclosure, the reactive gas containing hydrogen may include CH₄, H₂, etc. In embodiments of the present disclosure, the reactive gas containing hydrogen may have an etching selectivity (having relatively high etching rate) for Group VI elements contained in the chalcogenide material layer.

As the switching pattern 144 is formed, a shell region 144S may be formed at the side walls of the switching pattern 144 with a predetermined depth. The shell region 144S may be a region where some of Group VI elements, such as selenium (Se), has been removed from the side wall of the switching pattern 144 by the reactive ion etching process having a relatively high etching rate for Group VI elements. The shell region 144S may indicate the region where the composition of Group VI elements changed in comparison with an internal region (bulk region) of the switching pattern 144.

For example, as the second mask pattern M2 has a shape extending in the second horizontal direction Y, a pair of first shell regions 144S1 may be formed on both side walls (i.e., on both side walls newly exposed in the patterning process) that are spaced apart from each other in the second horizontal direction Y of the switching pattern 144. On the other hand, a corner region 144C may be formed at the four corners of the switching pattern 144. The corner region 144C may be a region that is formed after a portion of the pair of second shell regions 144S2 is exposed again in the patterning process using the second mask pattern M2 as an etch mask. For example, the corner region 144C may be a region in which some of Group VI elements, such as selenium (Se), has been removed from the side walls of the switching pattern 144 in the reactive ion etching process having a relatively high etching rate for Group VI elements.

The corner region 144C was exposed to patterning processes twice, and therefore, the corner region 144C may have the composition ratio of Group VI elements that is less than that of the pair of first shell regions 144S1, less than that of the pair of second shell regions 144S2, and less than that of the internal region (i.e., a bulk region) of the switching pattern 144.

After the corner region 144C and the pair of first shell regions 144S1 are formed, the internal region of the switching pattern 144 may be referred to as the main region 144M.

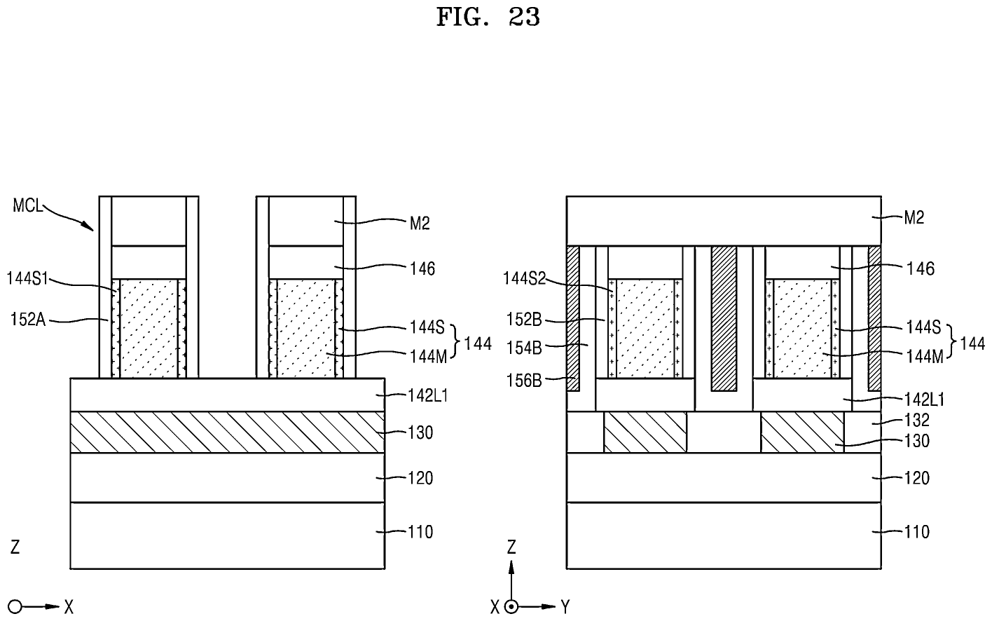

Referring to FIG. 23, a first spacer 152A may be formed on the side walls of the switching pattern 144 and the upper electrode layer 146. The first spacer 152A may be conformally formed with a relatively thin thickness, on the side walls of the switching pattern 144, the upper electrode 146, and the second mask pattern M2.

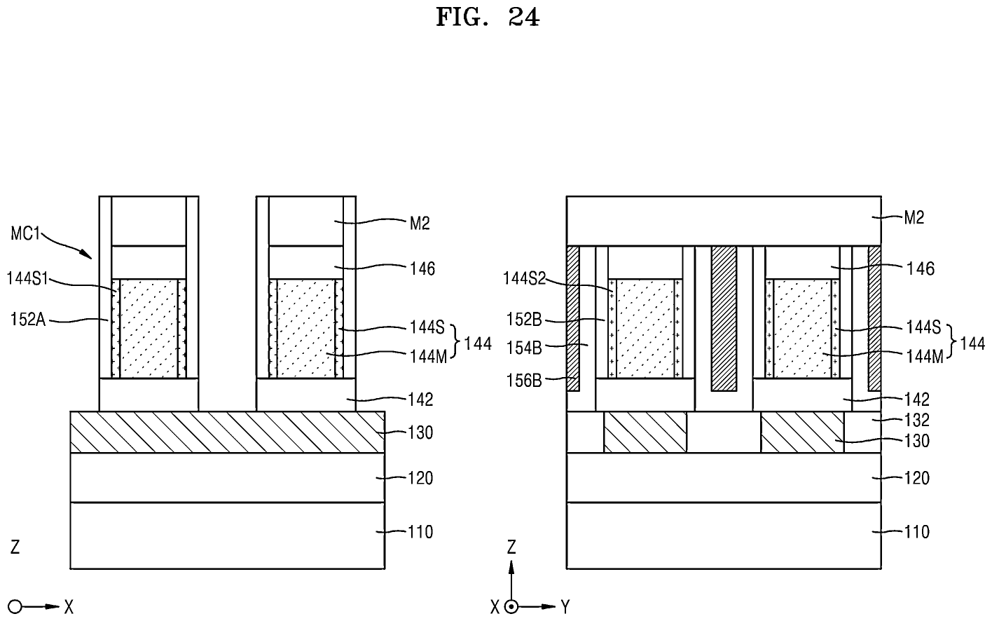

Referring to FIG. 24, a lower electrode layer 142 may be formed by patterning the lower electrode line 142L1 using the second mask pattern M2 and the first spacer 152A as an etch mask.

In embodiments of the present disclosure, etching gases containing oxygen may be used in the process of forming the lower electrode layer 142. In the etching atmosphere for forming the lower electrode layer 142, the side wall of the switching pattern 144 may be covered by the first spacer 152A and thus might not be exposed to the etching atmosphere.

Herein, a plurality of memory cells MC1 that each includes the lower electrode layer 142, the switching pattern 144, and the upper electrode layer 146, may be formed. The plurality of memory cells MC1 may be spaced apart from each other in the first horizontal direction X and in the second horizontal direction Y.

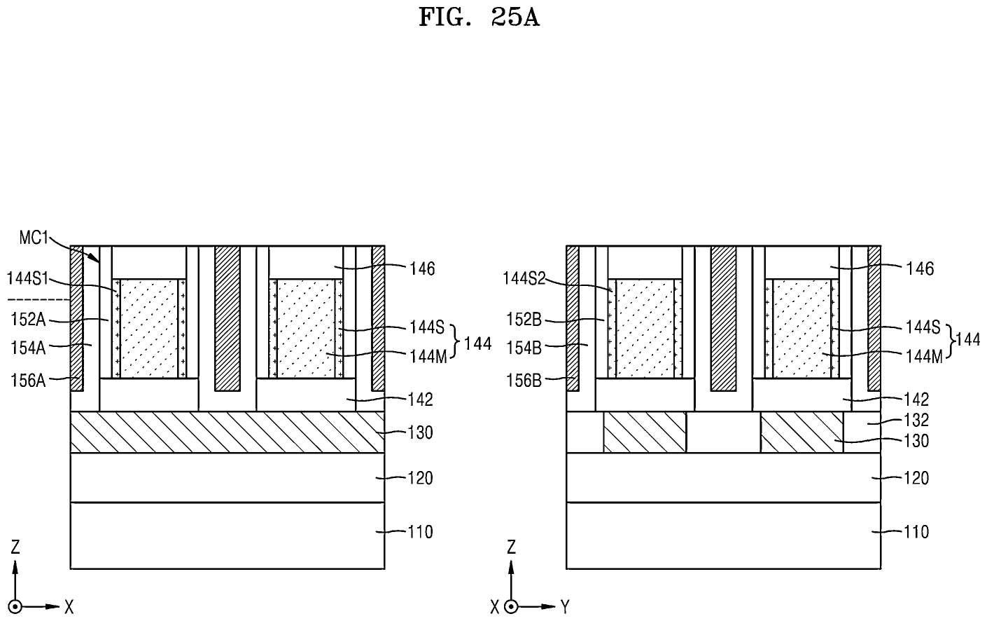

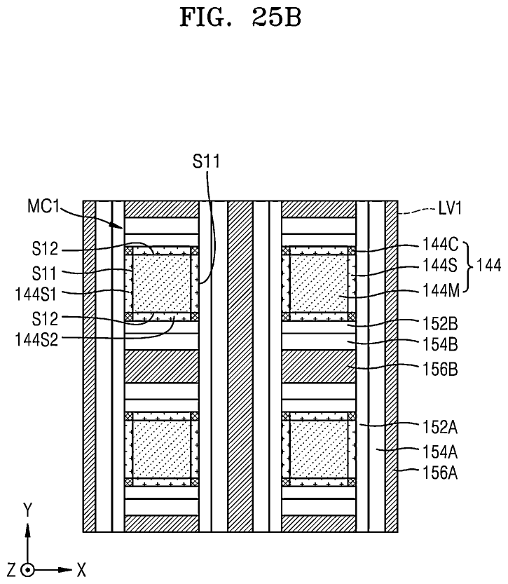

Referring to FIGS. 25A and 25B, a first encapsulation layer 154A may be formed on the side walls of the plurality of memory cells MC1. Thereafter, first buried insulating layers 156A may be formed on the first encapsulation layers 154B to fill spaces between adjacent memory cell MC1. The second mask pattern M2 may also be removed in the process of planarizing upper portions of the first buried layers 156A.

Referring to FIGS. 2 and 3, second conductive lines 160 may be formed on the plurality of memory cells MC1 and a second insulating layer 162 may be formed to fill spaces between the second conductive lines 160.

The memory device 100 may be manufactured by the above processes.

In the manufacturing process of the memory device 100, the shell region 144S and the corner region 144C may be formed on the side wall of the switching pattern 144, and the shell region 144S and the corner region 144C may have a decreased composition ratio of Group VI elements or increased composition ratios of Group IV elements and Group V elements compared to the bulk region or the internal region. Accordingly, an electrical path due to a local trap site may be formed through the corner region 144C of the switching pattern 144, and thus the memory device 100 may have fast operation speed and excellent operation reliability.

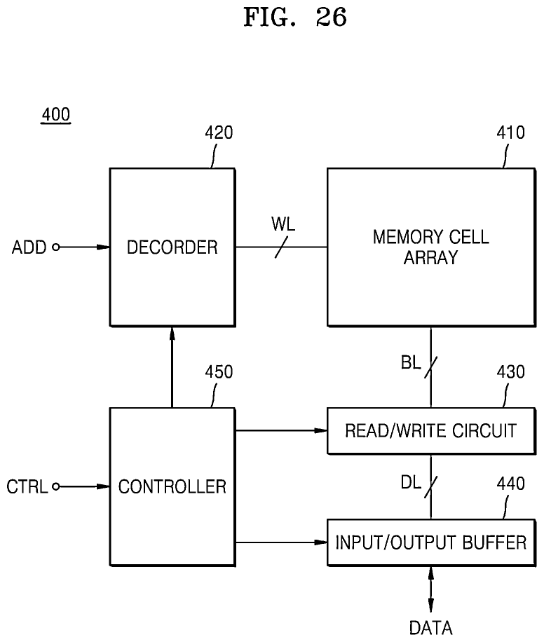

FIG. 26 is a configuration diagram of a memory device according to some embodiments of the present disclosure.

Referring to FIG. 26, a memory device 400, according to some embodiments of the present disclosure, may include a memory cell array 410, a decoder 420, a read/write circuit 430, an input/output buffer 440 and a controller 450. The memory cell array 410 may have similar characteristics to the memory device 100 described with reference to FIGS. 1 to 15.

A plurality of memory cells in the memory cell array 410 may be connected to the decoder 420 through a word line WL and may be connected to the read/write circuit 430 via a bit line BL.

The decoder 420 may receive an external address ADD and decode a low address and a column address to be accessed in the memory cell array 410 under the control of the controller 450 operating according to a control signal CTRL.

The read/write circuit 430 may receive data DATA from the input/output buffer 440 and a data line DL and write the data on the selected memory cell of the memory cell array 410 under the control of the controller 450, or provide the data read from a selected memory cell of the memory cell array 410 to the input/output buffer 440 under the control of the controller 450.

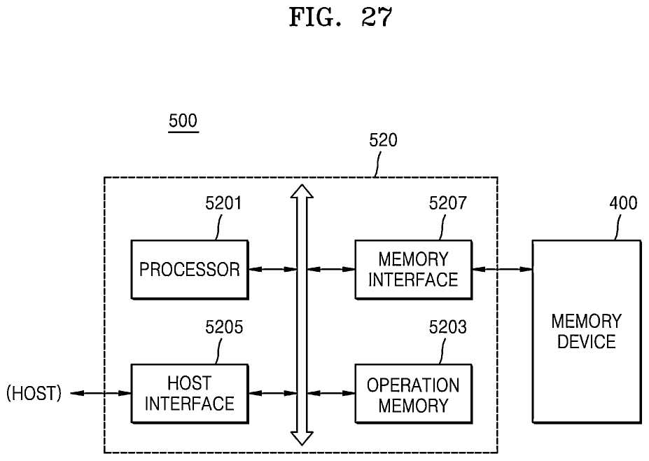

FIG. 27 is a configuration diagram of a data processing system including a memory device, according to some embodiments of the present disclosure.

Referring to FIG. 27, a data processing system 500 may include a memory controller 520 between a host and a memory device 400. The memory controller 520 may be configured to access the memory device 400 in response to needs of the host. The memory controller 520 may include a processor 5201, an operation memory 5203, a host interface 5205, and a memory interface 5207.

The processor 5201 may control the overall operation of the memory controller 520, and the operating memory 5203 may store the application, data, and control signals to be required for the operation of the memory controller 520. The host interface 5205 may perform the protocol conversion for data/control signal exchange between the host and the memory controller 520. The memory interface 5207 may perform the protocol conversion for data/control signal exchange between the memory controller 520 and the memory device 400. The memory device 400 may be the same as described above, and to the extent that an element is not described in detail with respect to this figure, it may be understood that the element is at least similar to a corresponding element that has been described elsewhere within the present disclosure. The data processing system 500 may be a memory card, but is not necessarily limited thereto.

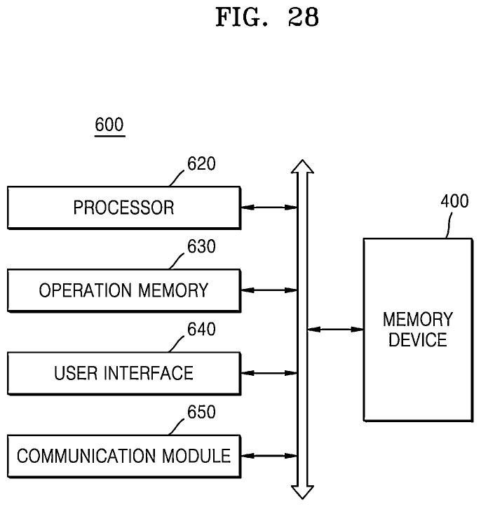

FIG. 28 is a configuration diagram of a data processing system including a memory device, according to some embodiments of the present disclosure.

Referring to FIG. 28, the data processing system 600 may include a memory device 400, a processor 620, an operation memory 630, and a user interface 640, and further include a communication module 650 as needed. The processor 620 may be a central processing device.

The operation memory 630 may store the application, data, and control signals to be required for the operation of the data processing system 600. The user interface 640 may provide an environment in which the user may access the data processing system 600 and provide the data processing process and results of the data processing system 600.

The memory device 400 may be the same as described above. The data processing system may be used as a disk device, as an internal/external memory card of a portable electronic device, or as an image processor and an application chipset.

While the inventive concept has been particularly shown and described with reference to embodiments thereof, it will be understood that various changes in form and details may be made therein without departing from the spirit and scope of the present disclosure.

What is claimed is:

1. A memory device, comprising:
a first conductive line extending in a first horizontal direction;
a second conductive line extending in a second horizontal direction; and
a memory cell disposed between the first conductive line and the second conductive line and extending in a vertical direction, the memory cell comprising a lower electrode layer, a switching pattern, and an upper electrode layer sequentially stacked on the first conductive line,
wherein the switching pattern comprises:
a main region extending in the vertical direction on the lower electrode layer, the main region comprising a pair of first side walls spaced apart from one another in the first horizontal direction and a pair of second walls spaced apart from one another in the second horizontal direction; and
a corner region disposed at four corners of the main region and extending in the vertical direction,
wherein the switching pattern comprises a chalcogenide layer comprising a Group VI chalcogen element on the periodic table, and an element of Group IV and an element of Group V of the periodic table, which are chemically bonded to the Group VI chalcogen element, and
wherein the concentration of the Group IV element, by atomic percent, in the corner region is greater than the concentration of the Group IV element, by atomic percent, in the main region, or
wherein the concentration of the Group V element, by atomic percent, in the corner region is greater than the concentration of the Group V element, by atomic percent, in the main region.

2. The memory device of claim 1, wherein the concentration ratio of the concentration of Group VI element, by atomic percent, to the concentration of the Group IV element, by atomic percent, in the corner region is greater than 0.5 and less than 1.

3. The memory device of claim 1, wherein the concentration ratio of the concentration of Group VI element, by atomic percent, to the concentration of the Group V element, by atomic percent, in the corner region is greater than 0.6 and less than 1.4.

4. The memory device of claim 1, wherein
the switching pattern further comprises:
a pair of first shell regions disposed on the pair of first side walls of the main region; and
a pair of second shell regions disposed on the pair of second side walls of the main region,
wherein the concentrations of the Group IV element, by atomic percent, in the pair of first shell regions and the pair of second shell regions are greater than the concentration of the Group IV element, by atomic percent, in the main region, or
wherein the concentrations of the Group V element, by atomic percent, in the pair of first shell regions and the pair of second shell regions are greater than the concentration of the Group V element, by atomic percent, in the main region.

5. The memory device of claim 4, wherein
the concentrations of the Group IV element, by atomic percent, in the pair of first shell regions and the pair of second shell regions are greater than the concentration of the Group IV element, by atomic percent, in the main region, and
the concentrations of the Group IV element, by atomic percent, in the pair of first shell regions and the pair of second shell regions are less than the concentration of the Group IV element, by atomic percent, in the corner region.

6. The memory device of claim 4, wherein
the concentrations of the Group V element, by atomic percent, in the pair of first shell regions and the pair of second shell regions are greater than the concentration of the Group V element, by atomic percent, in the main region, and
the concentrations of the Group V element, by atomic percent, in the pair of first shell regions and the pair of second shell regions are less than the concentration of the Group V element, by atomic percent, in the corner region.

7. The memory device of claim 1, wherein the Group VI chalcogen element comprises Te, Se, and/or S, the Group V element comprises As, Sb, and/or P, and the Group IV element comprises Si and/or Ge.

8. The memory device of claim 1, wherein the switching pattern further comprises a doped element of Group III of the periodic table.

9. The memory device of claim 8, wherein the doped element of Group III comprises In, Ga, and/or Al.

10. The memory device of claim 1, wherein the switching pattern is configured such that the concentration gradient of the Group IV element or the Group V element does not change from before to after the application of an operating voltage.

11. The memory device of claim 1, further comprising
a first spacer disposed on the pair of first side walls of the main region;
a first encapsulation layer disposed on the first spacer;
a second spacer disposed on the pair of second side walls of the main region; and
a second encapsulation layer disposed on the second spacer.

12. The memory device of claim 11, wherein
the switching pattern further comprises:
a pair of first shell regions disposed on the pair of first side walls of the main region, and
a pair of second shell regions disposed on the pair of second side walls of the main region,
wherein the first spacer directly contacts portions of side walls of the pair of first shell regions and a side wall of the corner region and extends in the second horizontal direction, and
wherein the second spacer directly contacts other portions of the side walls of the pair of second shell regions and the side wall of the corner region and extends in the first horizontal direction.

13. The memory device of claim 11, wherein
the main region is covered by the pair of first shell regions, the pair of second shell regions, and the corner region, and
the main region does not directly contact the first spacer and the second spacer.

14. A memory device, comprising:
a first conductive line extending in a first horizontal direction;
a second conductive line extending in a second horizontal direction; and
a memory cell disposed between the first conductive line and the second conductive line and extending in a vertical direction, the memory cell comprising a lower electrode layer, a switching pattern, and an upper electrode layer sequentially stacked on the first conductive line,
wherein the switching pattern comprises:
a main region disposed on the lower electrode layer and extending in the vertical direction, the main region comprising a pair of first side walls spaced apart from one another in the first horizontal direction and a pair of second walls spaced apart from one another in the second horizontal direction;
a pair of first shell regions disposed on the pair of first side walls of the main region;
a pair of second shell regions disposed on the pair of second side walls of the main region; and
a corner region extending in the vertical direction at four corners of the main region,
wherein the switching pattern comprises a chalcogenide layer comprising a Group VI chalcogen element of the periodic table and an element of Group IV and an element of Group V of the periodic table, which are chemically bonded to the Group VI chalcogen element, and
wherein the concentration of the Group IV element, by atomic percent, in the corner region is greater than the concentration of the Group IV element, by atomic percent, in the main region, or the concentration of the Group V element, by atomic percent, in the corner region is greater than the concentration of the Group V element, by atomic percent, in the main region.

15. The memory device of claim 14, further comprising:
a first spacer disposed on side walls of the pair of first shell regions;
a first encapsulation layer disposed on the first spacer;
a second spacer disposed on side walls of the pair of second shell regions; and
a second encapsulation layer disposed on the second spacer.

16. The memory device of claim 14, wherein
the concentration ratio of the concentration of Group VI element, by atomic percent, to the concentration of the Group IV element, by atomic percent, in the corner region is greater than 0.5 and less than 1, and
the concentration ratio of the concentration of Group VI element, by atomic percent, to the concentration of the Group V element, by atomic percent, in the corner region is greater than 0.6 and less than 0.8.

17. The memory device of claim 14, wherein
the concentrations of the Group IV element, by atomic percent, in the pair of first shell regions and the pair of second shell regions are greater than the concentration of the Group IV element, by atomic percent, in the main region, or
the concentrations of the Group V element, by atomic percent, in the pair of first shell regions and the pair of second shell regions are greater than the concentration of the Group V element, by atomic percent, in the main region.

18. The memory device of claim 14, wherein
the concentrations of the Group IV element, by atomic percent, in the pair of first shell regions and the pair of second shell regions are greater than the concentration of the Group IV element, by atomic percent, in the main region, and
the concentrations of the Group IV element, by atomic percent, in the pair of first shell regions and the pair of second shell regions are less than the concentration of the Group IV element, by atomic percent, in the corner region.

19. The memory device of claim 14, wherein
the concentrations of the Group V element, by atomic percent, in the pair of first shell regions and the pair of second shell regions are greater than the concentration of the Group V element, by atomic percent, in the main region, and
the concentrations of the Group V element, by atomic percent, in the pair of first shell regions and the pair of second shell regions are less than the concentration of the Group V element, by atomic percent, in the corner region.

20. A memory device, comprising:
a first conductive line extending in a first horizontal direction;
a second conductive line extending in a second horizontal direction;
a memory cell extending in a vertical direction and disposed between the first conductive line and the second conductive line, the memory cell comprising a lower electrode layer, a switching pattern, and an upper electrode layer sequentially stacked on the first conductive line;
a first spacer disposed on the pair of first side walls of the memory cell;
a first encapsulation layer disposed on the first spacer;
a second spacer disposed on the pair of second side walls of the memory cell; and
a second encapsulation layer disposed on the second spacer;
wherein the switching pattern comprises:
a main region extending in the vertical direction and disposed on the lower electrode layer, the main region comprising a pair of first side walls spaced apart from one another in the first horizontal direction and a pair of second walls spaced apart from one another in the second horizontal direction;
a pair of first shell regions disposed on the pair of first side walls of the main region;
a pair of second shell regions disposed on the pair of second side walls of the main region; and
a corner region extending in the vertical direction at four corners of the main region,
wherein the switching pattern comprises a chalcogenide layer comprising a Group VI chalcogen element of the periodic table, and an element of Group IV and an element of Group V of the periodic table, which are chemically bonded to the Group VI chalcogen element, and
wherein a concentration of the Group IV element, by atomic percent, in the corner region is greater than a concentration of the Group IV element, by atomic percent, in the main region, or the concentration of the Group V element, by atomic percent, in the corner region is greater than the concentration of the Group V element, by atomic percent, in the main region.
